(19) United States
(12) Patent Application Publication
(10) Pub. No.: US 2025/0180783 A1
(43) Pub. Date: Jun. 5, 2025

(54) OPTICAL SEMICONDUCTOR DEVICE AND DESIGN METHOD FOR ANTI-REFLECTION FILM USED IN OPTICAL SEMICONDUCTOR DEVICE

(71) Applicant: Mitsubishi Electric Corporation, Tokyo (JP)

(72) Inventor: Kimio SHIGIHARA, Tokyo (JP)

(73) Assignee: Mitsubishi Electric Corporation, Tokyo (JP)

(21) Appl. No.: 18/842,744

(22) PCT Filed: Apr. 14, 2022
(86) PCT No.: PCT/JP2022/017772

§ 371 Date: Aug. 29, 2024

(51) Int. Cl. G02B 1/115; G02B 27/00; H01S 5/028; H01S 5/34

(52) U.S. Cl. CPC G02B 1/115; G02B 27/0012; H01S 5/028; H01S 5/3402

(57) ABSTRACT

An optical semiconductor device of the present disclosure has an effective refractive index n_{c}, a wavelength λ, and an anti-reflection film formed of i coating films. The thickness of the kth coating film (1≤k≤i) is set at a value other than λ/2/nₖ. The refractive index of one or more coating films is greater than a refractive index n_{f} which is the square root of n_{c}. The refractive index of one or more coating films is smaller than n_{f}. A characteristic matrix of the multilayer coating film is equal to that of a single-layer coating film of which a refractive index is n_{f} and a thickness d_{f} is λ/4/n_{f}. The thicknesses of (i−3) coating films are set in advance. The thicknesses of the remaining three coating films are determined by solutions of three simultaneous equations derived from the characteristic matrix of the multilayer coating film.

### TECHNICAL FIELD

The present disclosure relates to an optical semiconductor device and an optical semiconductor device anti-reflection film design method.

### BACKGROUND ART

A conventional quantum-cascade laser device includes a semiconductor substrate, a semiconductor laminated structure formed on the semiconductor substrate, a first electrode formed above the semiconductor laminated structure, and a second electrode formed under the semiconductor substrate, and an anti-reflection (AR) film is formed at one of a pair of end surfaces that the semiconductor laminated structure including an active layer has, as described in, for example, Patent Document 1.

Patent Document 1 discloses that, in a case where the refractive index of the semiconductor laminated structure is 3.2, an anti-reflection film of which the reflectance at a center wavelength 10 μm of a laser beam is smaller than 0.1% can be obtained by a multilayer film having the following four-layer refractive index films: among a plurality of refractive index films forming the anti-reflection film, a first layer is a CeO₂ (cerium oxide) film of which the refractive index is 1.7 and the film thickness is 50 nm, a second layer is a ZnS (zinc sulfide) film of which the refractive index is 2.2 and the film thickness is 50 nm, a third layer is a CeF₃ (cerium fluoride) film of which the refractive index is 1.45 and the film thickness is 600 nm, and a fourth layer is a ZnS layer of which the refractive index is 2.2 and the film thickness is 450 nm.

Patent Document 2 discloses that, in a case where an anti-reflection film of which a refractive index n_{f} is equal to the square root of an effective refractive index n_{c} and the film thickness is λ/(4n_{f}) is provided on an end surface of a semiconductor laser device of which the effective refractive index is n_{c} and the oscillation wavelength is λ, an ideal single-layer film of which the reflectance becomes zero at the oscillation wavelength A can be replaced with a three-layer film composed of a film of which the refractive index is n₁ and the film thickness is d₁, a film of which the refractive index is n₂ and the film thickness is d₂, and a film of which the refractive index is n₃ and the film thickness is d₃.

Here, one of the refractive indices n₁, n₂, and n₃ is greater than the refractive index n_{f}, and one of the refractive indices n₁, n₂, and n₃ is smaller than the refractive index n_{f}. Further, it is disclosed that a film of which the refractive index is nₐ and the film thickness is λ/(2nₐ) is interposed at any position between the above films. However, this merely means a characteristic matrix of the film becomes an identity matrix, and there is neither description nor suggestion about replacing an ideal single-layer film with a film structure of four or more layers obtained by interposing a film having a characteristic matrix other than an identity matrix.

### CITATION LIST

### Patent Document

Patent Document 1: Japanese Laid-Open Patent Publication No. 2021-163922
Patent Document 2: Japanese Laid-Open Patent Publication No. 5-243689
Patent Document 3: WO2019/053854

### Non-Patent Document

Non-Patent Document 1: M. Born and E. Wolf, “Principles of Optics”, pp. 55-60, 6th Edition, PERGAMON PRESS

### SUMMARY OF THE INVENTION

### Problem to be Solved by the Invention

In the quantum-cascade laser device described in Patent Document 1, in the case where the refractive index of the semiconductor laminated structure is 3.2, the anti-reflection film of which the reflectance at the center wavelength 10 μm of a laser beam is smaller than 0.1% is formed by the multilayer film having four layers, i.e., from the end surface side of the semiconductor laminated structure, the first layer is a CeO₂ film of which the refractive index is 1.7 and the film thickness is 50 nm, the second layer is a ZnS film of which the refractive index is 2.2 and the film thickness is 50 nm, the third layer is a CeF₃ film of which the refractive index is 1.45 and the film thickness is 600 nm, and the fourth layer is a ZnS film of which the refractive index is 2.2 and the film thickness is 450 nm.

However, Patent Document 1 does not disclose how to determine each film thickness of the multilayer film, and therefore, if the refractive index of the semiconductor laminated structure or the refractive index of each film is changed, an appropriate anti-reflection film cannot be formed. That is, Patent Document 1 discloses nothing about an optical semiconductor device anti-reflection film design method. In addition, as described later, although the reflectance of the anti-reflection film at the center wavelength of the laser beam is smaller than 0.1%, the reflectance of the anti-reflection film at this wavelength does not become zero or minimum.

The semiconductor laser device anti-reflection film described in Patent Document 2 is formed such that, on the end surface of the semiconductor laser device of which the effective refractive index is n_{c} and the oscillation wavelength is λ, an ideal single-layer film of which the refractive index n_{f} is the square root of the effective refractive index n_{c} and the film thickness is λ/(4n_{f}) is replaced with a three-layer film, or a coating film of which the characteristic matrix becomes an identity matrix and of which the refractive index is nₐ and the film thickness is λ/(2nₐ) is interposed at any position between films after the replacement. That is, this anti-reflection film is not an anti-reflection film formed by a multilayer coating film having four or more layers in which the characteristic matrix of each coating film does not become an identity matrix.

The present disclosure has been made to solve the above problem, and an object of the present disclosure is to provide an optical semiconductor device having an anti-reflection film of which the reflectance becomes zero or minimum at a desired wavelength, i.e., a center wavelength of a laser beam, by replacing an ideal single-layer coating film with a multilayer coating film having four or more layers in which a characteristic matrix does not become an identity matrix, and provide an optical semiconductor device anti-reflection film design method therefor.

### Means to Solve the Problem

An optical semiconductor device according to the present disclosure is an optical semiconductor device of which an effective refractive index is n_{c} and a laser wavelength is λ, the optical semiconductor device having an anti-reflection film on one or both of end surfaces thereof. The anti-reflection film is formed by a multilayer coating film in which i coating films from a first coating film of which a refractive index is n₁ and a film thickness is d₁ to an ith coating film (i≥4) of which a refractive index is nᵢ and a film thickness is dᵢ, are laminated. A film thickness of a kth coating film in a kth layer (1≤k≤i) of the multilayer coating film is greater than λ/2/nₖ or smaller than λ/2/nₖ. A refractive index of at least one of the coating films of the multilayer coating film is greater than a refractive index n_{f} which is a square root of the effective refractive index n_{c}, and a refractive index of at least one of the coating films of the multilayer coating film is smaller than the refractive index n_{f}. A characteristic matrix of the multilayer coating film obtained by sequentially multiplying characteristic matrices from a characteristic matrix of the first coating film to a characteristic matrix of the ith coating film is equal to a characteristic matrix of an ideal single-layer coating film of which a refractive index is n_{f} and a film thickness d_{f} is λ/4/n_{f}. Film thicknesses of (i−3) coating films among the i coating films are film thicknesses set in advance. Film thicknesses of remaining three coating films among the i coating films are determined by solutions of three simultaneous equations derived from the characteristic matrix of the multilayer coating film.

An optical semiconductor device anti-reflection film design method according to the present disclosure is a design method for an anti-reflection film formed by a multilayer coating film in which i coating films (i≥4) are laminated and which is formed on one or both of end surfaces of an optical semiconductor device of which an effective refractive index is n_{c} and a laser wavelength is λ, the method including the steps of: for the i coating films, sequentially setting refractive indices and film thicknesses of the coating films such that a refractive index of a first coating film is n₁ and a film thickness thereof is dᵢ, and a refractive index of an ith coating film is n₁ and a film thickness thereof is dᵢ; setting a film thickness of a kth coating film in a kth layer (1≤k≤i) of the multilayer coating film, to be greater than λ/2/nₖ or smaller than λ/2/nₖ; selecting materials forming the coating films such that a refractive index of at least one of the coating films of the multilayer coating film is greater than a refractive index n_{f} which is a square root of the effective refractive index n_{c} and a refractive index of at least one of the coating films of the multilayer coating film is smaller than the refractive index n_{f}; assuming that a characteristic matrix of the multilayer coating film obtained by sequentially multiplying characteristic matrices from a characteristic matrix of the first coating film to a characteristic matrix of the ith coating film is equal to a characteristic matrix of an ideal single-layer coating film of which a refractive index is n_{f} and a film thickness d_{f} is λ/4/n_{f}; setting film thicknesses of (i−3) coating films among the i coating films in advance; and determining film thicknesses of remaining three coating films among the i coating films, by solutions of three simultaneous equations derived from the characteristic matrix of the multilayer coating film.

### Effect of the Invention

In the optical semiconductor device according to the present disclosure, for the anti-reflection film formed by the i-layer coating film (i≥4) formed on the end surface, the film thicknesses of three of the coating films are determined using a product of characteristic matrices, thus providing an effect that, even if the effective refractive index of the optical semiconductor device, the refractive index of a material forming the anti-reflection film, the order of coating films forming the anti-reflection film, or the like is changed, an optical semiconductor device having an anti-reflection film of which the reflectance becomes zero or minimum at a desired wavelength can be easily obtained.

In the optical semiconductor device anti-reflection film design method according to the present disclosure, designing is performed such that, for the anti-reflection film formed by the i-layer coating film (i≥4) formed on the end surface, the film thicknesses of three of the coating films are determined using a product of characteristic matrices, thus providing an effect that, even if the effective refractive index of the optical semiconductor device, the refractive index of a material forming the anti-reflection film, the order of coating films forming the anti-reflection film, or the like is changed, an optical semiconductor device anti-reflection film of which the reflectance becomes zero or minimum at a desired wavelength can be easily designed.

### BRIEF DESCRIPTION OF THE DRAWINGS

FIG. 1 is an overall view showing a quantum-cascade laser device which is an example of an optical semiconductor device according to embodiment 1;

FIG. 2 is a sectional view along line A-A in FIG. 1, of the quantum-cascade laser device which is an example of the optical semiconductor device according to embodiment 1;

FIG. 3 is a schematic view showing an example of the structure of an anti-reflection film of the quantum-cascade laser device which is an example of the optical semiconductor device according to embodiment 1;

FIG. 4 shows a wavelength dependence of a reflectance in an example of the anti-reflection film of the quantum-cascade laser device which is an example of the optical semiconductor device according to embodiment 1;

FIG. 5 shows a wavelength dependence of a reflectance in another example of the anti-reflection film of the quantum-cascade laser device which is an example of the optical semiconductor device according to modification 1 of embodiment 1;

FIG. 6 is a schematic view showing the structure of an anti-reflection film of a quantum-cascade laser device which is an example of an optical semiconductor device according to embodiment 2;

FIG. 7 shows a wavelength dependence of a reflectance of the anti-reflection film of the quantum-cascade laser device which is an example of the optical semiconductor device according to embodiment 2;

FIG. 8 is a schematic view showing the structure of an anti-reflection film of a quantum-cascade laser device which is an example of an optical semiconductor device according to embodiment 3;

FIG. 9 shows a wavelength dependence of a reflectance of the anti-reflection film of the quantum-cascade laser device which is an example of the optical semiconductor device according to embodiment 3;

FIG. 10 is a schematic view showing the structure of an anti-reflection film of a quantum-cascade laser device which is an example of an optical semiconductor device according to embodiment 4;

FIG. 11 shows a wavelength dependence of a reflectance of the anti-reflection film of the quantum-cascade laser device which is an example of the optical semiconductor device according to embodiment 4;

FIG. 12 is an overall view showing the structure of a broad-area semiconductor laser device of which the oscillation wavelength is 975 nm and which is an example of an optical semiconductor device according to embodiment 5.

FIG. 13 is a schematic view showing the structure of an anti-reflection film of the broad-area semiconductor laser device of which the oscillation wavelength is 975 nm and which is an example of the optical semiconductor device according to embodiment 5;

FIG. 14 shows a wavelength dependence of a reflectance of the anti-reflection film of the broad-area semiconductor laser device of which the oscillation wavelength is 975 nm and which is an example of the optical semiconductor device according to embodiment 5.

### DESCRIPTION OF EMBODIMENTS

### Embodiment 1

### <Structure of Optical Semiconductor Device According to Embodiment 1>

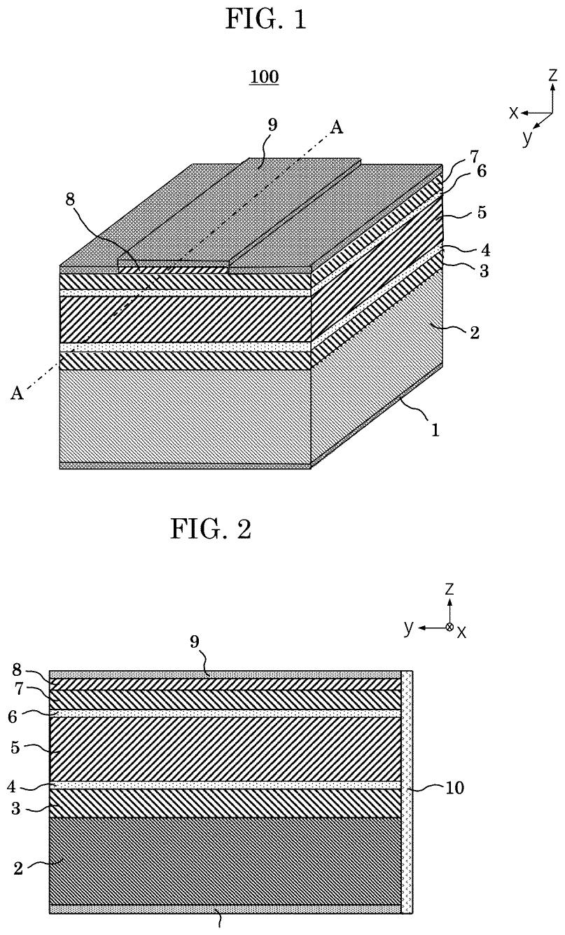

FIG. 1 is an overall view of a quantum-cascade laser device which is an example of an optical semiconductor device 100 according to embodiment 1. The quantum-cascade laser device includes a bottom-side n-type electrode 1, an n-type InP substrate 2, an n-type InP buffer layer 3, an n-type GaInAs first light confinement layer 4, a core region 5 formed of 30 to 40 stages, an n-type GaInAs second light confinement layer 6, an n-type InP cladding layer 7, an n-type GaInAs contact layer 8, and a top-side n-type electrode 9.

The stages of the core region 5 form a multiple quantum well (MQW) in which quantum well layers made of GaInAs and barrier layers made of AlInAs are alternately laminated in multiple layers. The oscillation wavelength of the quantum-cascade laser device is 3 to 24 μm which corresponds to mid-wavelength infrared light. In FIG. 1, an anti-reflection film 10 provided on an end surface of the quantum-cascade laser device is not shown.

During operation of the quantum-cascade laser device, the bottom-side n-type electrode 1 is biased to minus and the top-side n-type electrode 9 is biased to plus. In operation, voltage is applied between the bottom-side n-type electrode 1 and the top-side n-type electrode 9, whereby current is injected into the quantum-cascade laser device, to cause laser oscillation.

FIG. 2 is a sectional view of the quantum-cascade laser device along line A-A in FIG. 1. As shown in FIG. 2, the anti-reflection film 10 is provided at a front end surface of the quantum-cascade laser device.

### <Optical Semiconductor Device Anti-Reflection Film Design Method>

A characteristic matrix in a case where a coating film of which the refractive index is n and the film thickness is d is provided on an end surface of a quantum-cascade laser device is represented by the following Formula (1). In Formula (1), Φ is a phase term. Where the laser wavelength of the quantum-cascade laser device is denoted by λ, Φ can be represented by the following Formula (2). In Formula (2), i is an imaginary unit.

$$\begin{matrix}[ Mathematical 1 ] & \\ ( \begin{matrix}cos ϕ & \frac{- i}{n} sin ϕ \\ - in sin ϕ & cos ϕ\end{matrix} ) & ( 1 )\end{matrix}$$

$$ϕ = 2 π nd / λ \qquad ( 2 )$$

The effective refractive index of the quantum-cascade laser device is denoted by n_{c}, and a refractive index n_{f} is defined as the square root of the effective refractive index n_{c}. When a coating film of which a film thickness d_{f} is λ/(4n_{f}) is provided on the end surface of the quantum-cascade laser device, the characteristic matrix is represented by the following Formula (3). In Formula (3), a reflectance R becomes zero at the wavelength A. Hereinafter, this single-layer coating film may be referred to as an ideal single-layer coating film.

$$\begin{matrix}[ Mathematical 2 ] & \\ ( \begin{matrix}0 & \frac{- i}{{n}_{f}} \\ - {in}_{f} & 0\end{matrix} ) & ( 3 )\end{matrix}$$

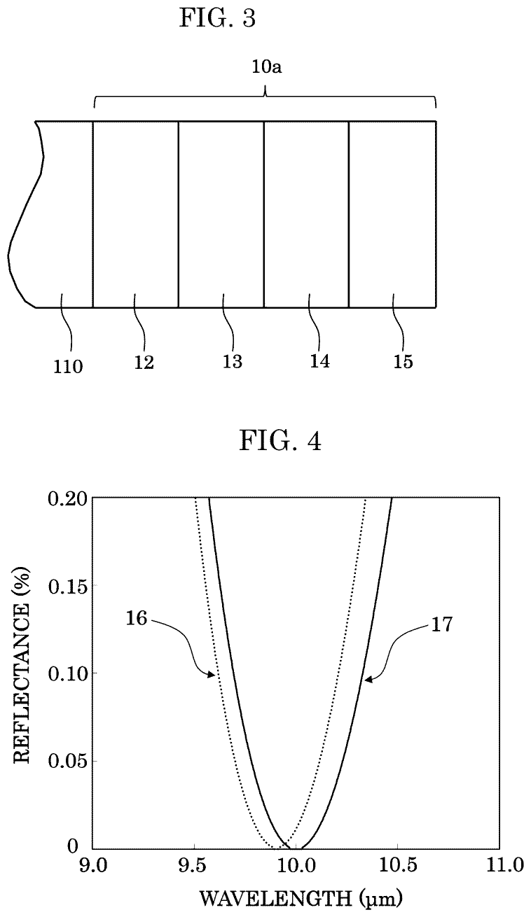

A method for replacing the ideal single-layer coating film with a multilayer coating film having four layers will be described below. FIG. 3 is a schematic view showing an example of the multilayer coating film having four layers. In FIG. 3, an anti-reflection film 10a is formed by a four-layer coating film including, from the end surface side of a quantum-cascade laser device 110 of which the effective refractive index n_{c} is 3.2, a first coating film 12 which is made of CeO₂ and of which a refractive index n₁ is 1.70 and a film thickness dᵢ is 50 nm, a second coating film 13 which is made of YF₃ (yttrium fluoride) and of which a refractive index n₂ is 1.40 and a film thickness is d₂, a third coating film 14 which is made of ZnS and of which a refractive index n₃ is 2.20 and a film thickness is d₃, and a fourth coating film 15 which is made of CeF₃ and of which a refractive index n₄ is 1.45 and a film thickness is d₄. Hereinafter, for example, the first coating film 12 made of CeO₂ may be referred to as CeO₂ first coating film 12, and the other coating films may be referred to in the same way.

In the above structure of the anti-reflection film 10a, the film thickness dᵢ of the CeO₂ first coating film 12 is set at 50 nm, but the film thickness dᵢ is not limited thereto and can be arbitrarily set. The film thickness d₂ of the YF₃ second coating film 13, the film thickness d₃ of the ZnS third coating film 14, and the film thickness d₄ of the CeF₃ fourth coating film 15 are unknowns but are film thickness values calculated by a method described later. The desired wavelength λ is 10 μm. The characteristic matrix of the above four-layer coating film can be represented by the following Formula (4). Here, m₁₁, m₁₂, m₂₁, m₂₂ are matrix terms.

$$\begin{matrix}[ Mathematical 3 ] & \\ ( \begin{matrix}{m}_{11} & {m}_{12} \\ {m}_{21} & {m}_{22}\end{matrix} ) ≡ ( \begin{matrix}cos {ϕ}_{1} & \frac{- i}{{n}_{1}} sin {ϕ}_{1} \\ - {in}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - {in}_{2} sin {ϕ}_{2} & cos {ϕ}_{2}\end{matrix} ) \times ( \begin{matrix}cos {ϕ}_{3} & \frac{- i}{{n}_{3}} sin {ϕ}_{3} \\ - {in}_{3} sin {ϕ}_{3} & cos {ϕ}_{3}\end{matrix} ) ( \begin{matrix}cos {ϕ}_{4} & \frac{- i}{{n}_{4}} sin {ϕ}_{4} \\ - {in}_{4} sin {ϕ}_{4} & cos {ϕ}_{4}\end{matrix} ) & ( 4 )\end{matrix}$$

Phase terms Φ₁, Φ₂, Φ₃, and Φ₄ in Formula (4) are represented by the following Formula (5).

$$\begin{matrix}[ Mathematical 4 ] & \\ \begin{matrix}{ϕ}_{1} = 2 π {n}_{1} {d}_{1} / λ \\ {ϕ}_{2} = 2 π {n}_{2} {d}_{2} / λ \\ {ϕ}_{3} = 2 π {n}_{3} {d}_{3} / λ \\ {ϕ}_{4} = 2 π {n}_{4} {d}_{4} / λ\end{matrix} \} & ( 5 )\end{matrix}$$

The refractive index n₁ of the CeO₂ first coating film 12 is known and the film thickness d₁ is a film thickness value set in advance. Therefore, the phase term Φ₁ is a numerical value that can be calculated. Thus, unknowns are three phase terms Φ₂, Φ₃, and Φ₄. Since the number of unknowns is three, for example, three simultaneous equations are solved as shown by Formula (6), whereby the film thicknesses d₂, d₃, and d₄ are calculated from Formula (6). The refractive index of each coating film is a numerical value unique to a material forming the coating film, i.e., a known numerical value. In this regard, the refractive index of the material forming each coating film can have a certain variation width depending on a film formation condition, but the refractive index is regarded as a known numerical value, including such a variation width.

$$\begin{matrix}[ Mathematical 5 ] & \\ \begin{matrix}{m}_{11} = 0 \\ {m}_{12} = \frac{- i}{{n}_{f}} \\ {m}_{21} = - {in}_{f}\end{matrix} \} & ( 6 )\end{matrix}$$

The layer thicknesses of the coating films calculated from Formula (6) are as follows: d₂=513.38 nm, d₃=374.58 nm, and d₄=574.57 nm. According to a calculation result, it is found that the reflectance R becomes minimum at a wavelength of 10.09 μm and does not become minimum at a desired wavelength of 10 μm.

With respect to three unknowns, four equations can be created. Therefore, the three unknowns can be obtained using any three equations, but the reflectance R that becomes minimum at a desired wavelength might not appear. Accordingly, since the term m₁₁ at the first row and the first column and the term m₂₂ at the second row and the second column for the ideal single-layer coating film are both zero, as shown by the following Formula (7), three equations are created using all of the four terms of the matrix and the three equations are solved simultaneously.

$$\begin{matrix}[ Mathematical 6 ] & \\ \begin{matrix}{m}_{11} = {m}_{22} \\ {m}_{12} = \frac{- i}{{n}_{f}} \\ {m}_{21} = - {in}_{f}\end{matrix} \} & ( 7 )\end{matrix}$$

In this case, as solutions of the three simultaneous equations, the layer thicknesses of the coating films are obtained as follows: d₂=493.74 nm, d₃=387.37 nm, and d₄=557.57 nm. According to Non-Patent Document 1, the reflectance R can be represented by the following Formula (8). Thus, the wavelength dependence of the reflectance R can be calculated.

$$\begin{matrix}[ Mathematical 7 ] & \\ \begin{matrix}R = {\vert r \vert}^{2} \\ = {\vert \frac{( {m}_{11} + {m}_{12} ) nc - ( {m}_{21} + {m}_{22} )}{( {m}_{11} + {m}_{12} ) nc + ( {m}_{21} + {m}_{22} )} \vert}^{2}\end{matrix} & ( 8 )\end{matrix}$$

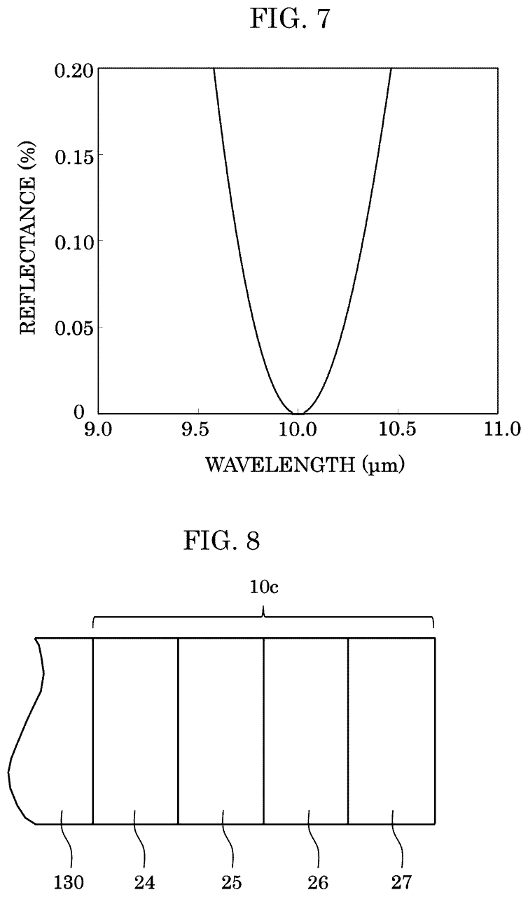

FIG. 4 shows the wavelength dependence of the reflectance R of the anti-reflection film 10a formed by the four-layer coating film according to embodiment 1, together with an anti-reflection film formed by a four-layer coating film shown in FIG. 7 in Patent Document 1. A dotted-line curve 16 and a solid-line curve 17 respectively represent the wavelength dependences of the reflectances R of the anti-reflection film formed by the four-layer coating film described in Patent Document 1 and the anti-reflection film 10a formed by the four-layer coating film according to embodiment 1.

In the anti-reflection film 10a formed by the four-layer coating film according to embodiment 1, as is found from the solid-line curve 17, the reflectance R becomes minimum (zero) at the desired wavelength λ=10 μm, and a bandwidth in which the reflectance R is not greater than 0.1% is as wide as 634 nm. On the other hand, in the anti-reflection film formed by the four-layer coating film shown in FIG. 7 in Patent Document 1, as is found from the dotted-line curve 16, the reflectance R does not become minimum (zero) at the desired wavelength λ=10 μm, and a bandwidth in which the reflectance R is not greater than 0.1% is as narrow as 589 nm. That is, also in comparison of film thickness configurations, it is found that the anti-reflection film 10a formed by the four-layer coating film according to embodiment 1 is clearly different from the anti-reflection film formed by the four-layer coating film described in Patent Document 1.

In order to make the characteristic matrix of the ideal single-layer coating film and the characteristic matrix of the four-layer coating film coincide with each other, the refractive index of one or more of the coating films of the four-layer coating film is to be greater than the refractive index n_{f} of the ideal single-layer coating film and the refractive index of one or more of the coating films of the four-layer coating film is to be smaller than the refractive index n_{f} of the ideal single-layer coating film.

Since the anti-reflection film 10a formed by the four-layer coating film according to embodiment 1 is to replace the ideal single-layer coating film, the total film thickness of the above four-layer coating film is 1489 nm, which is close to the film thickness d_{f}=1398 nm of the ideal single-layer coating film, and thus the entire film thickness of the anti-reflection film is thin. Therefore, in the anti-reflection film 10a formed by the four-layer coating film according to embodiment 1, film strain which would be a problem in a thick anti-reflection film is small and film peeling is less likely to occur, so that an effect of improving reliability of the quantum-cascade laser device is provided.

The reason why CeO₂ is used as the material forming the first coating film 12 of the anti-reflection film 10a is to keep favorable adhesion between the coating film and the semiconductor forming the quantum-cascade laser device.

In embodiment 1, the quantum-cascade laser device formed on the InP substrate has been shown as an example of the optical semiconductor device 100. However, without limitation thereto, for example, a semiconductor laser device formed on a GaAs substrate is also applicable.

### <Effects of Optical Semiconductor Device According to Embodiment 1>

As described above, in the optical semiconductor device according to embodiment 1, a four-layer coating film in which refractive indices are known and in which the film thicknesses of any three layers are unknowns and the film thickness of the remaining one layer is set in advance is provided on an end surface of the optical semiconductor device of which the effective refractive index is n_{c}, and where the refractive index n_{f} is defined as the square root of the effective refractive index n_{c}, three simultaneous equations derived by assuming that a product of the characteristic matrices of the coating films is equal to the characteristic matrix of an ideal single-layer coating film of which the refractive index is n_{f} and the film thickness is λ/(4n_{f}), are solved to determine the film thicknesses of the three layers which are unknowns, thus providing an effect that, even if the effective refractive index n_{c} of the optical semiconductor device, the refractive index of a material forming the anti-reflection film, the order of coating films forming the anti-reflection film, or the like is changed, an optical semiconductor device having an anti-reflection film of which the reflectance R becomes minimum at a desired wavelength λ is easily obtained.

### <Effects of Optical Semiconductor Device Anti-Reflection Film Design Method According to Embodiment 1>

As described above, the optical semiconductor device anti-reflection film design method according to embodiment 1 executes the steps of: prescribing that refractive indices are known and that the film thicknesses of any three layers are assumed to be unknowns and the film thickness of the remaining one layer is set in advance, for a four-layer coating film on an end surface of the optical semiconductor device of which the effective refractive index is n_{c}; and where the refractive index n_{f} is defined as the square root of the effective refractive index n_{c}, solving three simultaneous equations derived by assuming that a product of the characteristic matrices of the coating films is equal to the characteristic matrix of an ideal single-layer coating film of which the refractive index is n_{f} and the film thickness is λ/(4n_{f}), to determine the film thicknesses of the three layers which are unknowns, thereby designing the film thicknesses of the coating films of the four-layer coating film, thus providing an effect that, even if the effective refractive index n_{c} of the optical semiconductor device, the refractive index of a material forming the anti-reflection film, the order of coating films forming the anti-reflection film, or the like is changed, an optical semiconductor device anti-reflection film of which the reflectance R becomes minimum at a desired wavelength λ can be easily designed.

### Modification 1 of Embodiment 1

In embodiment 1, the film thickness d₁ of the CeO₂ first coating film 12 is set at 50 nm. However, the film thickness of any of the coating films of the four-layer coating film may be arbitrarily set. For example, in a case where the film thickness d₂ of the YF₃ second coating film 13 is set at 70 nm, the film thickness d₁ of the CeO₂ first coating film 12, the film thickness d₃ of the ZnS third coating film 14, and the film thickness d₄ of the CeF₃ fourth coating film 15 are unknowns. By solving three simultaneous equations in the same manner as in embodiment 1, the film thicknesses other than the film thickness d₂ set in advance in the four-layer coating film are calculated as follows: d₁=759.47 nm, d₃=262.43 nm, and d₄=347.32 nm. In the anti-reflection film 10a formed by the above four-layer coating film, the reflectance R becomes minimum (zero) at the desired wavelength λ=10 μm. FIG. 5 shows the wavelength dependence of the reflectance R of the anti-reflection film 10a formed by the above four-layer coating film.

In a case where the film thickness d₃ of the ZnS third coating film 14 is set at 300 nm, the film thickness d₁ of the CeO₂ first coating film 12, the film thickness d₂ of the YF₃ second coating film 13, and the film thickness d₄ of the CeF₃ fourth coating film 15 are unknowns, and by solving three simultaneous equations in the same manner, the layer thicknesses other than the film thickness d₃ set in advance in the four-layer coating film are calculated as follows: d₁=625.84 nm, d₂=148.88 nm, and d₄=366.72 nm. In the anti-reflection film 10a formed by the above four-layer coating film, the reflectance R becomes minimum (zero) at the desired wavelength λ=10 μm.

In a case where the film thickness d₄ of the CeF₃ fourth coating film 15 is set at 500 nm, the film thickness d₁ of the CeO₂ first coating film 12, the film thickness d₂ of the YF₃ second coating film 13, and the film thickness d₃ of the ZnS third coating film 14 are unknowns, and by solving three simultaneous equations in the same manner, the film thicknesses other than the film thickness d₄ set in advance in the four-layer coating film are calculated as follows: d₁=182.38 nm, d₂=408.55 nm, and d₃=380.00 nm. In the anti-reflection film 10a formed by the above four-layer coating film, the reflectance R becomes minimum (zero) at the desired wavelength λ=10 μm. As described above, the film thickness of any one of the coating films of the four-layer coating film may be a film thickness value set in advance, and the film thickness value may be arbitrarily set.

### <Effects of Optical Semiconductor Device According to Modification 1 of Embodiment 1>

As described above, in the optical semiconductor device according to modification 1 of embodiment 1, a four-layer coating film in which refractive indices are known and in which the film thicknesses of any three layers are unknowns and the film thickness of the remaining one layer is set in advance is provided on an end surface of the optical semiconductor device of which the effective refractive index is n_{c}, and where the refractive index n_{f} is defined as the square root of the effective refractive index n_{c}, three simultaneous equations derived by assuming that a product of the characteristic matrices of the coating films is equal to the characteristic matrix of an ideal single-layer coating film of which the refractive index is n_{f} and the film thickness is λ/(4n_{f}), are solved to determine the film thicknesses of the three layers which are unknowns, thus providing an effect that, even if the effective refractive index n_{c} of the optical semiconductor device, the refractive index of a material forming the anti-reflection film, the order of coating films forming the anti-reflection film, or the like is changed, an optical semiconductor device having an anti-reflection film of which the reflectance R becomes minimum at a desired wavelength λ is easily obtained.

### Embodiment 2

An optical semiconductor device according to embodiment 2 has an anti-reflection film formed by a multilayer coating film having more than four layers, i.e., five or more layers. The optical semiconductor device anti-reflection film design method for the four-layer coating film described in embodiment 1 is applicable in the same manner to an anti-reflection film 10b formed by a multilayer coating film having more than four layers, which is provided to the optical semiconductor device according to embodiment 2, and this will be described below.

### <Structure of Optical Semiconductor Device According to Embodiment 2>

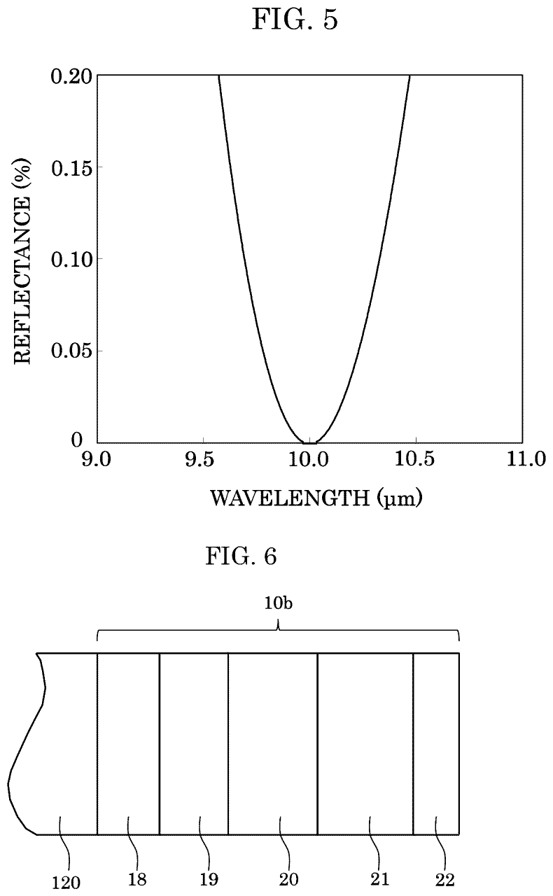

FIG. 6 is a schematic view showing the structure of the anti-reflection film 10b formed by a five-layer coating film of a quantum-cascade laser device 120 which is an example of the optical semiconductor device according to embodiment 2. As shown in FIG. 6, the anti-reflection film 10b is formed by a five-layer coating film including, from the end surface side of the quantum-cascade laser device 120 of which the effective refractive index n_{c} is 3.2, a first coating film 18 which is made of CeO₂ and of which a refractive index n₁ is 1.70 and a film thickness d₁ is 200 nm, a second coating film 19 which is made of ZnS and in which a refractive index n₂ is 2.20 and a film thickness d₂ is 100 nm, a third coating film 20 which is made of YF₃ and of which a refractive index n₃ is 1.40 and a film thickness is d₃, a fourth coating film 21 which is made of ZnSe (zinc selenide) and of which a refractive index n₄ is 2.41 and a film thickness is d₄, and a fifth coating film 22 which is made of CeF₃ and of which a refractive index n₅ is 1.45 and a film thickness is d₅.

### <Optical Semiconductor Device Anti-Reflection Film Design Method According to Embodiment 2>

In the above five-layer coating film, the film thickness d₁ of the CeO₂ first coating film 18 is set at 200 nm and the film thickness d₂ of the ZnS second coating film 19 is set at 100 nm. However, the film thickness values are not limited thereto and may be arbitrarily set. The film thickness d₃ of the YF₃ third coating film 20, the film thickness d₄ of the ZnSe fourth coating film 21, and the film thickness d₅ of the CeF₃ fifth coating film 22 are unknowns. The desired wavelength λ is 10 μm. The characteristic matrix of the anti-reflection film 10b formed by the above five-layer coating film can be represented by the following Formula (9).

$$\begin{matrix}[ Mathematical 8 ] & \\ ( \begin{matrix}{m}_{11} & {m}_{12} \\ {m}_{21} & {m}_{22}\end{matrix} ) ≡ ( \begin{matrix}cos {ϕ}_{1} & \frac{- i}{{n}_{1}} sin {ϕ}_{1} \\ - {in}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - {in}_{2} sin {ϕ}_{2} & cos {ϕ}_{2}\end{matrix} ) ( \begin{matrix}cos {ϕ}_{3} & \frac{- i}{{n}_{3}} sin {ϕ}_{3} \\ - {in}_{3} sin {ϕ}_{3} & cos {ϕ}_{3}\end{matrix} ) \times ( \begin{matrix}cos {ϕ}_{4} & \frac{- i}{{n}_{4}} sin {ϕ}_{4} \\ - {in}_{4} sin {ϕ}_{4} & cos {ϕ}_{4}\end{matrix} ) ( \begin{matrix}cos {ϕ}_{5} & \frac{- i}{{n}_{5}} sin {ϕ}_{5} \\ - {in}_{5} sin {ϕ}_{5} & cos {ϕ}_{5}\end{matrix} ) & ( 9 )\end{matrix}$$

In Formula (9), phase terms Φ₁, Φ₂, Φ₃, Φ₄, and Φ₅ are represented by the following Formula (10).

$$\begin{matrix}[ Mathematical 9 ] & \\ \begin{matrix}{ϕ}_{1} = 2 π {n}_{1} {d}_{1} / λ \\ {ϕ}_{2} = 2 π {n}_{2} {d}_{2} / λ \\ {ϕ}_{3} = 2 π {n}_{3} {d}_{3} / λ \\ {ϕ}_{4} = 2 π {n}_{4} {d}_{4} / λ \\ {ϕ}_{5} = 2 π {n}_{5} {d}_{5} / λ\end{matrix} \} & ( 10 )\end{matrix}$$

The refractive index n₁ of the CeO₂ first coating film 18 and the refractive index n₂ of the ZnS second coating film 19 are known, and the film thickness d₁ of the CeO₂ first coating film 18 and the film thickness d₂ of the ZnS second coating film 19 are set film thickness values. Therefore, the phase terms Φ₁ and Φ₂ are numerical values that can be calculated. Thus, unknowns are three phase terms Φ₃, Φ₄, and Φ₅. Since the number of unknowns is three, three simultaneous equations are solved in the same manner as in embodiment 1, whereby the film thicknesses of the remaining three layers of the five-layer coating film are calculated as follows: d₃=466.88 nm, d₄=256.20 nm, and d₅=412.65 nm. In the anti-reflection film 10b formed by the above five-layer coating film, the reflectance R becomes minimum (zero) at the desired wavelength λ=10 μm. FIG. 7 shows the wavelength dependence of the reflectance R of the anti-reflection film 10b formed by the above five-layer coating film. A bandwidth in which the reflectance R is not greater than 0.1% is 625 nm.

In embodiment 2, the film thicknesses of the CeO₂ first coating film 18 and the ZnS second coating film 19 of the five-layer coating film forming the anti-reflection film 10b are film thickness values set in advance. However, without limitation to these film thickness values, the film thicknesses of any two layers of the five-layer coating film may be set in advance and the film thickness values of the two layers may be arbitrarily set.

In embodiment 2, the five-layer coating film has been shown as the multilayer coating film forming the anti-reflection film 10b. However, by applying the above optical semiconductor device anti-reflection film design method, it is possible to determine film thicknesses also for a multilayer coating film having six or more layers, in the same manner. Where the number of layers of the multilayer coating film forming the anti-reflection film is denoted by i (i≥4), the film thicknesses of any (i−3) coating films of the i coating films may be arbitrarily set in advance.

In order to make the characteristic matrix of the ideal single-layer coating film and the characteristic matrix of the i-layer coating film (i≥4) coincide with each other, the refractive index of one or more of the coating films of the i-layer coating film is to be greater than the refractive index n_{f} of the ideal single-layer coating film and the refractive index of one or more of the coating films of the i-layer coating film is to be smaller than the refractive index n_{f} of the ideal single-layer coating film.

Hereinafter, a case of the i-layer coating film having i coating films will be described. In the case of the i-layer coating film, the characteristic matrix of the i-layer coating film can be represented by the following Formula (11).

$$\begin{matrix}[ Mathematical 10 ] & \\ ( \begin{matrix}{m}_{11} & {m}_{12} \\ {m}_{21} & {m}_{22}\end{matrix} ) ≡ ( \begin{matrix}cos {ϕ}_{1} & \frac{- i}{{n}_{1}} sin {ϕ}_{1} \\ - {in}_{1} sin {ϕ}_{1} & cos {ϕ}_{1}\end{matrix} ) ( \begin{matrix}cos {ϕ}_{2} & \frac{- i}{{n}_{2}} sin {ϕ}_{2} \\ - {in}_{2} sin {ϕ}_{2} & cos {ϕ}_{2}\end{matrix} ) \times … ( \begin{matrix}cos {ϕ}_{i} & \frac{- i}{{n}_{i}} sin {ϕ}_{i} \\ - {in}_{i} sin {ϕ}_{i} & cos {ϕ}_{i}\end{matrix} ) & ( 11 )\end{matrix}$$

In Formula (11), the phase terms Φ₁, Φ₂, . . . , Φᵢ are represented by the following Formula (12).

$$\begin{matrix}[ Mathematical 11 ] & \\ \begin{matrix}{ϕ}_{1} = 2 π {n}_{1} {d}_{1} / λ \\ {ϕ}_{2} = 2 π {n}_{2} {d}_{2} / λ \\ ⋮ \\ {ϕ}_{i} = 2 π {n}_{i} {d}_{i} / λ\end{matrix} \} & ( 12 )\end{matrix}$$

The film thicknesses of any (i−3) coating films of the i coating films may be arbitrarily set in advance. Thus, since the number of unknowns in Formula (11) is three, three simultaneous equations are solved in the same manner as in embodiment 1, whereby the film thicknesses of the remaining three coating films can be calculated.

Steps in a design method for an anti-reflection film formed by a multilayer coating film in which i coating films (i≥4) are laminated and which is formed on one or both of end surfaces of an optical semiconductor device of which the effective refractive index is n_{c} and the laser wavelength is λ, i.e., an optical semiconductor device anti-reflection film design method, will be summarized below.

### (First Step)

For the i coating films, the refractive indices and film thicknesses of the respective coating films are sequentially set such that the refractive index of the first coating film is n₁ and the film thickness thereof is dᵢ, and the refractive index of the ith coating film is nᵢ and the film thickness thereof is dᵢ. The values of the refractive indices are known.

### (Second Step)

The film thickness of the kth coating film in the kth layer (1≤k≤i) of the multilayer coating film is set to be greater than λ/2/nₖ or smaller than λ/2/nₖ.

### (Third Step)

Materials forming the coating films are selected such that the refractive index of at least one of the coating films of the multilayer coating film is greater than the refractive index n_{f} which is the square root of the effective refractive index n_{c} and the refractive index of at least one of the coating films of the multilayer coating film is smaller than the refractive index n_{f}.

### (Fourth Step)

The characteristic matrix of the multilayer coating film obtained by sequentially multiplying characteristic matrices from the characteristic matrix of the first coating film to the characteristic matrix of the ith coating film is assumed to be equal to the characteristic matrix of the ideal single-layer coating film of which the refractive index is n_{f} and the film thickness d_{f} is λ/4/n_{f}.

### (Fifth Step)

The film thicknesses of (i−3) coating films among the i coating films forming the multilayer coating film are set in advance.

### (Sixth Step)

The film thicknesses of the remaining three coating films other than the (i−3) coating films among the i coating films forming the multilayer coating film are determined by solutions of three simultaneous equations derived from the characteristic matrix of the multilayer coating film.

### Effects of Embodiment 2

As described above, in the optical semiconductor device and the optical semiconductor device anti-reflection film design method according to embodiment 2, an i-layer coating film (i≥4) in which refractive indices are known and the film thicknesses of the remaining three coating films other than any (i−3) coating films for which the film thicknesses are set in advance are unknowns is provided on an end surface of the optical semiconductor device of which the effective refractive index is n_{c}, and where the refractive index n_{f} is defined as the square root of the effective refractive index n_{c}, three simultaneous equations derived by assuming that a product of the characteristic matrices of the coating films is equal to the characteristic matrix of an ideal single-layer coating film of which the refractive index is n_{f} and the film thickness is λ/(4n_{f}), are solved to determine the film thicknesses of the three layers which are unknowns, thus providing an effect that, even if the effective refractive index n_{c} of the optical semiconductor device, the refractive index of a material forming the anti-reflection film, the order of coating films forming the anti-reflection film, or the like is changed, an optical semiconductor device having an anti-reflection film of which the reflectance R becomes minimum at a desired wavelength A, and an optical semiconductor device anti-reflection film design method therefor, are easily obtained.

### Embodiment 3

FIG. 8 is a schematic view showing the structure of an anti-reflection film 10c in a case where an effective refractive index n_{c} of the quantum-cascade laser device 130 which is an example of an optical semiconductor device according to embodiment 3 is 3.3. The effective refractive index n_{c} of a quantum-cascade laser device changes depending on an element structure such as configurations and compositions of a core region, a light confinement layer, and a cladding layer.

### <Structure of Optical Semiconductor Device According to Embodiment 3>

As shown in FIG. 8, the anti-reflection film 10c is formed by a four-layer coating film including, from the end surface side of the quantum-cascade laser device 130 of which the effective refractive index n_{c} is 3.3, a first coating film 24 which is made of CeO₂ and of which the refractive index n₁ is 1.70 and a film thickness is d₁, a second coating film 25 which is made of YF₃ and of which a refractive index n₂ is 1.40 and a film thickness is d₂, a third coating film 26 which is made of ZnS and of which a refractive index n₃ is 2.20 and a film thickness d₃ is 300 nm, and a fourth coating film 27 which is made of CeF₃ and of which a refractive index n₄ is 1.45 and a film thickness is d₄.

In the above four-layer coating film, the film thickness d₃ of the ZnS third coating film 26 is set at 300 nm. However, the film thickness value is not limited thereto and may be arbitrarily set. The film thickness d₁ of the CeO₂ first coating film 24, the film thickness d₂ of the YF₃ second coating film 25, and the film thickness d₄ of the CeF₃ fourth coating film 27 are unknowns. The desired wavelength λ is 10 μm.

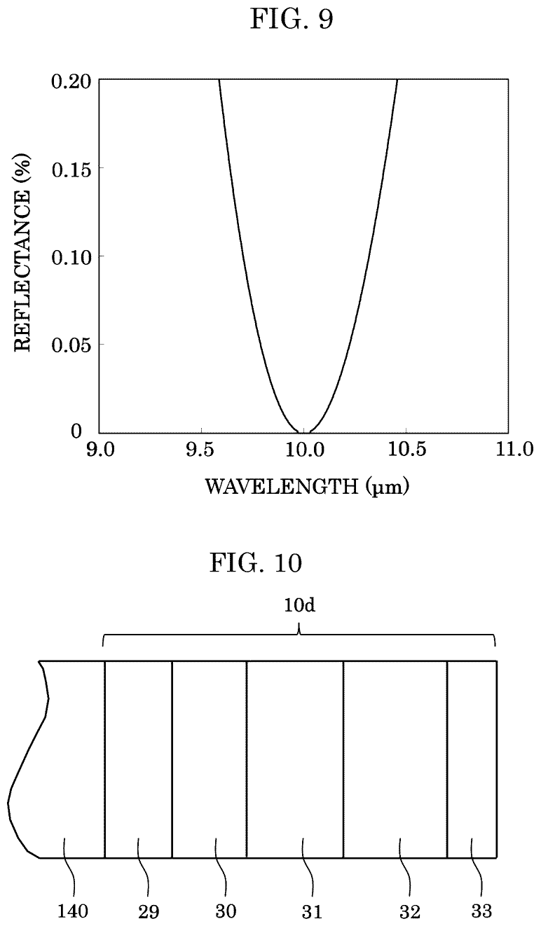

Since the number of unknowns is three, three simultaneous equations are solved in the same manner as in embodiment 1, whereby the film thicknesses other than the film thickness d₃ set in advance in the four-layer coating film are calculated as follows: d₁=709.60 nm, d₂=58.32 nm, and d₄=357.95 nm. In the anti-reflection film 10c formed by the above four-layer coating film, the reflectance R becomes minimum (zero) at the desired wavelength λ=10 μm. FIG. 9 shows the wavelength dependence of the reflectance R of the anti-reflection film 10c formed by the four-layer coating film. A bandwidth in which the reflectance R is not greater than 0.1% is 614 nm. The effective refractive index n_{c} of the quantum-cascade laser device is not limited to 3.2 or 3.3, and the effective refractive index n_{c} may be set at another value.

### Effects of Embodiment 3

As described above, in the optical semiconductor device and the optical semiconductor device anti-reflection film design method according to embodiment 3, a four-layer coating film in which refractive indices are known and in which the film thicknesses of any three layers are unknowns and the film thickness of the remaining one layer is set in advance is provided on an end surface of the optical semiconductor device of which the effective refractive index is 3.3, and where the refractive index n_{f} is defined as the square root of the effective refractive index n_{c}, three simultaneous equations derived by assuming that a product of the characteristic matrices of the coating films is equal to the characteristic matrix of an ideal single-layer coating film of which the refractive index is n_{f} and the film thickness is λ/(4n_{f}), are solved to determine the film thicknesses of the three layers which are unknowns, thus providing an effect that, even if the effective refractive index n_{c} of the optical semiconductor device, the refractive index of a material forming the anti-reflection film, the order of coating films forming the anti-reflection film, or the like is changed, an optical semiconductor device having an anti-reflection film of which the reflectance R becomes minimum at a desired wavelength A, and an optical semiconductor device anti-reflection film design method therefor, are easily obtained.

### Embodiment 4

FIG. 10 is a schematic view showing the structure of an anti-reflection film 10d formed by a five-layer coating film in a case where an effective refractive index n_{c} of a quantum-cascade laser device 140 which is an example of an optical semiconductor device according to embodiment 4 is 3.2. A quantum-cascade laser device oscillates using intersubband transition and therefore can oscillate with a wavelength in a range of 3 μm to 24 μm. The quantum-cascade laser device 140 has an anti-reflection film 10d corresponding to a laser wavelength of 11 μm as an example of another laser wavelength different from the laser wavelength 10 μm of the quantum-cascade laser devices 110, 120, and 130 of embodiments 1 to 3.

### <Structure of Optical Semiconductor Device According to Embodiment 4>

As shown in FIG. 10, the anti-reflection film 10d is formed by a five-layer coating film including, from the end surface side of the quantum-cascade laser device 140 of which the effective refractive index n_{c} is 3.2, a first coating film 29 which is made of CeO₂ and of which a refractive index n₁ is 1.70 and a film thickness d₁ is 200 nm, a second coating film 30 which is made of ZnS and of which a refractive index n₂ is 2.20 and a film thickness d₂ is 100 nm, a third coating film 31 which is made of YF₃ and of which a refractive index n₃ is 1.40 and a film thickness is d₃, a fourth coating film 32 which is made of ZnSe and of which a refractive index n₄ is 2.41 and a film thickness is d₄, and a fifth coating film 33 which is made of CeF₃ and of which a refractive index n₅ is 1.45 and a film thickness is d₅.

In the above five-layer coating film, the film thickness d₁ of the CeO₂ first coating film 29 is set at 200 nm and the film thickness d₂ of the ZnS second coating film 30 is set at 100 nm, in advance. However, the film thickness values are not limited thereto and may be arbitrarily set. The film thickness d₃ of the YF₃ third coating film 31, the film thickness d₄ of the ZnSe fourth coating film 32, and the film thickness d₅ of the CeF₃ fifth coating film 33 are unknowns. The desired wavelength λ is 11 μm.

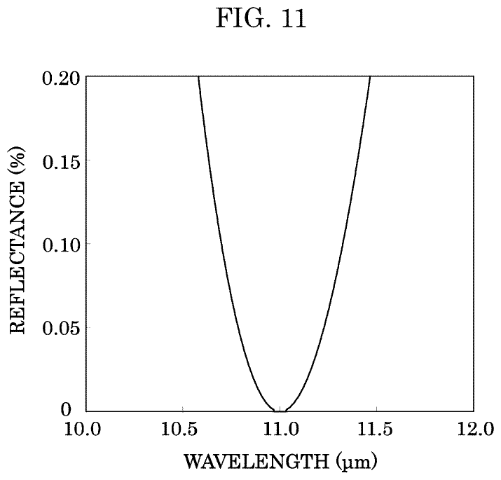

Since the number of unknowns is three, three simultaneous equations are solved in the same manner as in embodiment 2, whereby the film thicknesses other than the film thickness d₁ and the film thickness d₂ set in advance in the five-layer coating film are calculated as follows: d₃=522.43 nm, d₄=286.93 nm, and d₅=474.50 nm. In the anti-reflection film 10d formed by the five-layer coating film, the reflectance R becomes minimum (zero) at the desired wavelength λ=11 μm. FIG. 11 shows the wavelength dependence of the reflectance R of the anti-reflection film 10d formed by the five-layer coating film. A bandwidth in which the reflectance R is not greater than 0.1% is 625 nm. The oscillation wavelength of the quantum-cascade laser device is not limited to 10 μm or 11 μm, and may be any wavelength in a range of 3 μm to 24 μm.

### Effects of Embodiment 4

As described above, in the optical semiconductor device and the optical semiconductor device anti-reflection film design method according to embodiment 4, a five-layer coating film in which refractive indices are known and in which the film thicknesses of any three layers are unknowns and the film thicknesses of the remaining two layers are set in advance is provided on an end surface of the optical semiconductor device of which the effective refractive index n_{c} is 3.2, and where the refractive index n_{f} is defined as the square root of the effective refractive index n_{c}, three simultaneous equations derived by assuming that a product of the characteristic matrices of the coating films is equal to the characteristic matrix of an ideal single-layer coating film of which the refractive index is n_{f} and the film thickness is λ/(4n_{f}), are solved to determine the film thicknesses of the three layers which are unknowns, thus providing an effect that, even if the effective refractive index n_{c} of the optical semiconductor device, the refractive index of a material forming the anti-reflection film, the order of coating films forming the anti-reflection film, or the like is changed, an optical semiconductor device having an anti-reflection film of which the reflectance R becomes minimum at a desired wavelength of 11 μm, and an optical semiconductor device anti-reflection film design method therefor, are obtained.

### Embodiment 5

In embodiments 1 to 4, the quantum-cascade laser devices 110, 120, 130, and 140 have been described as examples of the optical semiconductor device. However, without limitation to a quantum-cascade laser device, the present disclosure is applicable to various optical semiconductor devices having an anti-reflection film on an end surface thereof.

### <Structure of Optical Semiconductor Device According to Embodiment 5>

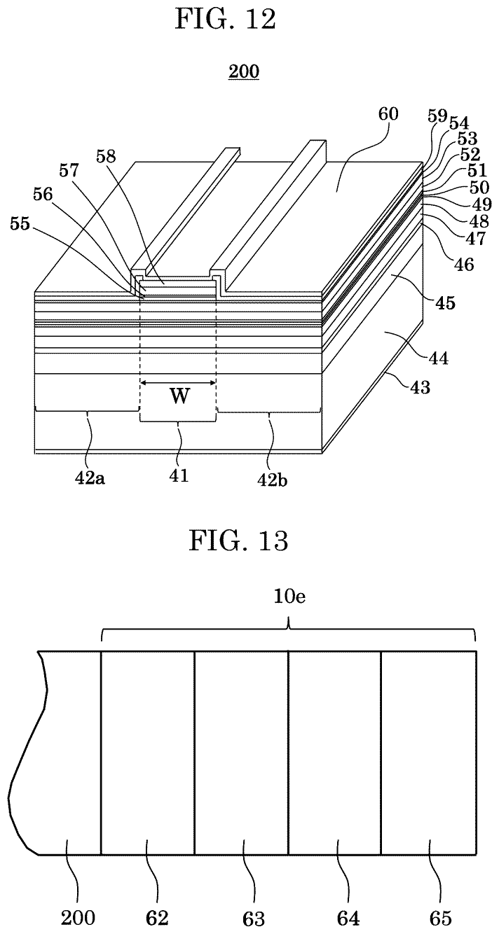

As an example of an optical semiconductor device according to embodiment 5, a broad-area semiconductor laser device 200 of which the oscillation wavelength is 975 nm and which has an anti-reflection film 10e formed by a multilayer coating film, will be described. FIG. 12 is an overall view of the broad-area semiconductor laser device 200 of which the oscillation wavelength is 975 nm and of which the element structure is disclosed in Patent Document 3.

The broad-area semiconductor laser device 200 has an active region 41 having a width W, and cladding regions 42a and 42b. The broad-area semiconductor laser device 200 includes an n-type electrode 43, an n-type GaAs substrate 44, an n-type Al_{0.20}Ga_{0.80}As first cladding layer 45 of which an Al composition ratio is 0.20 and a layer thickness is 1.3 μm, an n-type Al_{0.25}Ga_{0.75}As second cladding layer 46 of which an Al composition ratio is 0.25 and a layer thickness is 0.2 mm, an n-side Al_{0.26}Ga_{0.04}As first guide layer 47 of which an Al composition ratio is 0.16 and a layer thickness is 1.05 μm, an n-side Al_{0.14}Ga_{0.86}As second guide layer 48 of which an Al composition ratio is 0.14 and a layer thickness is 0.1 μm, an n-side GaAs_{0.88}P_{0.12} barrier layer 49 of which a P composition ratio is 0.12 and a layer thickness is 8 nm, an In_{0.12}Ga_{0.88}As active layer 50 of which an In composition ratio is 0.12 and a layer thickness is 8 nm, a p-side GaAs_{0.88}P_{0.12} barrier layer 51 of which a P composition ratio is 0.12 and a layer thickness is 8 nm, a p-side Al_{0.14}Ga_{0.86}As first guide layer 52 of which an Al composition ratio is 0.14 and a layer thickness is 0.35 μm, a p-side Al_{0.16}Ga_{0.04}As second guide layer 53 of which an Al composition ratio is 0.16 and a layer thickness is 0.30 μm, a p-type Al_{0.55}Ga_{0.45}As first etching stop layer 54 of which an Al composition ratio is 0.55 and a layer thickness is 40 nm, a p-type Al_{0.25}Ga_{0.75}As first cladding layer 55 of which an Al composition ratio is 0.25 and a layer thickness is 0.1 μm, a p-type Al_{0.55}Ga_{0.45}As second etching stop layer 56 of which an Al composition ratio is 0.55 and a layer thickness is 40 nm, a p-type Al_{0.25}Ga_{0.75}As second cladding layer 57 of which an Al composition ratio is 0.25 and a layer thickness is 1.4 μm, a p-type GaAs contact layer 58 of which a layer thickness is 0.2 μm, a SiN film 59, and a p-type electrode 60.

In the broad-area semiconductor laser device 200, the In composition ratio and the layer thickness of the In_{0.2}Ga_{0.88}As active layer 50 are adjusted so that the oscillation wavelength λ becomes 975 nm. The effective refractive index in the active region 41 and the effective refractive index in the cladding regions 42a and 42b are 3.41739 and 3.41658, respectively. Since a laser beam is mainly present in the active region 41, 3.41739 is used as the effective refractive index n_{c} of the broad-area semiconductor laser device 200, in discussion of the anti-reflection film below.

FIG. 13 is a schematic view showing the structure of the anti-reflection film 10e provided on an end surface of the broad-area semiconductor laser device 200 of which the oscillation wavelength is 975 nm and which is an example of the optical semiconductor device according to embodiment 5. As shown in FIG. 13, the anti-reflection film 10e is formed by a four-layer coating film including, from the end surface side of the broad-area semiconductor laser device 200 of which the effective refractive index n_{c} is 3.41739, a first coating film 62 which is made of Al₂O₃ (aluminium oxide) and of which a refractive index n₁ is 1.63 and a film thickness is d₁, a second coating film 63 which is made of Ta₂O₅ (tantalum pentoxide) and of which a refractive index n₂ is 2.00 and a film thickness is d₂, a third coating film 64 which is made of Al₂O₃ and of which a refractive index n₃ is 1.63 and a film thickness d₃ is 100 nm, and a fourth coating film 65 which is made of SiO₂ (silicon dioxide) and of which a refractive index n₄ is 1.45 and a film thickness is d₄.

In the above four-layer coating film, the film thickness d₃ of the Al₂O₃ third coating film 64 is set at 100 nm. However, the film thickness value is not limited thereto and may be arbitrarily set. The film thickness d₁ of the Al₂O₃ first coating film 62, the film thickness d₂ of the Ta₂O₅ second coating film 63, and the film thickness d₄ of the SiO₂ fourth coating film 65 are unknowns. The desired wavelength λ is 0.975 μm (975 nm).

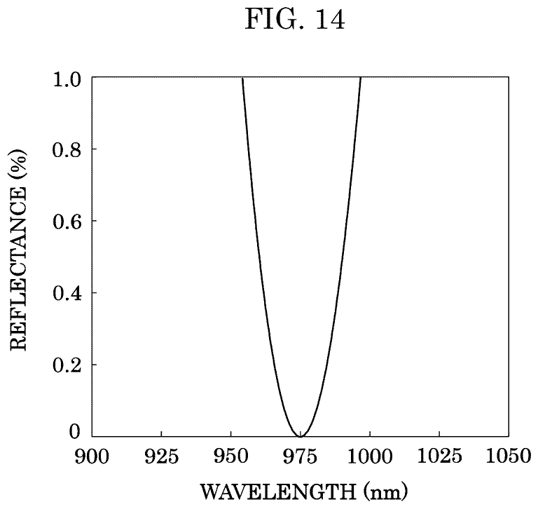

Since the number of unknowns is three, three simultaneous equations are solved in the same manner as in embodiment 1, whereby the film thicknesses other than the film thickness d₃ set in advance in the four-layer coating film are calculated as follows: d₁=310.63 nm, d₂=77.80 nm, and d₄=271.67 nm. In the anti-reflection film 10e formed by the above four-layer coating film, the reflectance R becomes minimum (zero) at the desired wavelength λ=0.975 μm. FIG. 14 shows the wavelength dependence of the reflectance R of the anti-reflection film 10e formed by the four-layer coating film.

In embodiment 5, Ta₂O₅ is used as a material having a greater refractive index than the refractive index n_{f} which is the square root of the effective refractive index n_{c} of the broad-area semiconductor laser device 200. However, instead of Ta₂O₅, amorphous Si may be used.

### Effects of Embodiment 5

As described above, in the optical semiconductor device and the optical semiconductor device anti-reflection film design method according to embodiment 5, a four-layer coating film in which refractive indices are known and in which the film thicknesses of any three layers are unknowns and the film thickness of the remaining one layer is set in advance is provided on an end surface of the broad-area semiconductor laser device of which the oscillation wavelength λ is 975 nm and which is an example of the optical semiconductor device, and where the refractive index n_{f} is defined as the square root of the effective refractive index n_{c}, three simultaneous equations derived by assuming that a product of the characteristic matrices of the coating films is equal to the characteristic matrix of an ideal single-layer coating film of which the refractive index is n_{f} and the film thickness is λ/(4n_{f}), are solved to determine the film thicknesses of the three layers which are unknowns, thus providing an effect that, even if the effective refractive index n_{c} of the broad-area semiconductor laser device of which the oscillation wavelength λ is 975 nm, the refractive index of a material forming the anti-reflection film, the order of coating films forming the anti-reflection film, or the like is changed, an optical semiconductor device having an anti-reflection film of which the reflectance R becomes minimum at the oscillation wavelength of 975 nm, and an optical semiconductor device anti-reflection film design method therefor, are easily obtained.

In each embodiment, the refractive indices of coating films change depending on the film formation method or the like. Therefore, the refractive indices of the materials shown in each embodiment are merely examples. The anti-reflection film of the present disclosure can be realized by any multilayer coating film having such a structure that includes one or more materials having greater refractive indices than the refractive index n_{f} of the ideal single-layer coating film and one or more materials having smaller refractive indices than the refractive index n_{f} of the ideal single-layer coating film. As described above, the anti-reflection film according to the present disclosure is applicable to various optical semiconductor devices without depending on the wavelength and the element structure.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 bottom-side n-type electrode
2 n-type InP substrate
3 n-type InP buffer layer
4 n-type GaInAs first light confinement layer
5 core region
6 n-type GaInAs second light confinement layer
7 n-type InP cladding layer
8 n-type GaInAs contact layer
9 top-side n-type electrode
10, 10a, 10b, 10c, 10d, 10e anti-reflection film
12, 18, 24, 29 CeO₂ first coating film
13, 25 YF₃ second coating film
14, 26 ZnS third coating film
15, 27 CeF₃ fourth coating film
19, 30 ZnS second coating film
20, 31 YF₃ third coating film
21, 32 ZnSe fourth coating film
22, 33 CeF₃ fifth coating film
41 active region
42a, 42b cladding region
43 n-type electrode
44 n-type GaAs substrate
45 n-type Al_{0.20}Ga_{0.80}As first cladding layer
46 n-type Al_{0.25}Ga_{0.75}As second cladding layer
47 n-side Al_{0.16}Ga_{0.04}As first guide layer
48 n-side Al_{0.14}Ga_{0.86}As second guide layer
49 n-side GaAs_{0.88}P_{0.12} barrier layer
50 In_{0.12}Ga_{0.88}As active layer
51 p-side GaAs_{0.88}P_{0.12} barrier layer
52 p-side Al_{0.14}Ga_{0.86}As first guide layer
53 p-side Al_{0.16}Ga_{0.04}As second guide layer
54 p-type Al_{0.55}Ga_{0.45}As first etching stop layer
55 p-type Al_{0.25}Ga_{0.75}As first cladding layer
56 p-type Al_{0.55}Ga_{0.45}As second etching stop layer
57 p-type Al_{0.25}Ga_{0.75}As second cladding layer
58 p-type GaAs contact layer
59 SiN film
60 p-type electrode
100 optical semiconductor device
110, 120, 130, 140 quantum-cascade laser device
200 broad-area semiconductor laser device

1. An optical semiconductor device of which an effective refractive index is n_{c} and a laser wavelength is λ, the optical semiconductor device having an anti-reflection film on one or both of end surfaces thereof, wherein
the anti-reflection film is formed by a multilayer coating film in which i coating films from a first coating film of which a refractive index is n₁ and a film thickness is d₁ to an ith coating film (i≥4) of which a refractive index is n₁ and a film thickness is dᵢ, are laminated,
a film thickness of a kth coating film in a kth layer (1≤k≤i) of the multilayer coating film is greater than λ/2/nₖ or smaller than λ/2/nₖ,
a refractive index of at least one of the coating films of the multilayer coating film is greater than a refractive index n_{f} which is a square root of the effective refractive index n_{c}, and a refractive index of at least one of the coating films of the multilayer coating film is smaller than the refractive index n_{f},
a characteristic matrix of the multilayer coating film obtained by sequentially multiplying characteristic matrices from a characteristic matrix of the first coating film to a characteristic matrix of the ith coating film is equal to a characteristic matrix of an ideal single-layer coating film of which a refractive index is n_{f} and a film thickness d_{f} is λ/4/n_{f},
film thicknesses of (i−3) coating films among the i coating films are film thicknesses set in advance, and
film thicknesses of remaining three coating films among the i coating films are determined by solutions of three simultaneous equations derived from the characteristic matrix of the multilayer coating film.

2. The optical semiconductor device according to claim 1, wherein
the anti-reflection film is formed by a four-layer coating film.

3. The optical semiconductor device according to claim 1, wherein
the anti-reflection film is formed by a five-layer coating film.

4. The optical semiconductor device according to claim 1, wherein
the optical semiconductor device is a semiconductor laser device.

5. The optical semiconductor device according to claim 1, wherein
the optical semiconductor device is a quantum-cascade semiconductor laser device.

6. The optical semiconductor device according to claim 1, wherein
each of the coating films is made of one material of CeO₂, YF₃, ZnS, CeF₃, ZnSe, Al₂O₃, Ta₂O₅, SiO₂, and amorphous Si.

7. An optical semiconductor device anti-reflection film design method for an anti-reflection film formed by a multilayer coating film in which i coating films (i≥4) are laminated and which is formed on one or both of end surfaces of an optical semiconductor device of which an effective refractive index is n_{c} and a laser wavelength is λ, the method comprising the steps of:
for the i coating films, sequentially setting refractive indices and film thicknesses of the coating films such that a refractive index of a first coating film is n₁ and a film thickness thereof is d₁, and a refractive index of an ith coating film is nᵢ and a film thickness thereof is dᵢ;
setting a film thickness of a kth coating film in a kth layer (1≤k≤i) of the multilayer coating film, to be greater than λ/2/nₖ or smaller than λ/2/nₖ;
selecting materials forming the coating films such that a refractive index of at least one of the coating films of the multilayer coating film is greater than a refractive index n_{f} which is a square root of the effective refractive index n_{c} and a refractive index of at least one of the coating films of the multilayer coating film is smaller than the refractive index n_{f};
assuming that a characteristic matrix of the multilayer coating film obtained by sequentially multiplying characteristic matrices from a characteristic matrix of the first coating film to a characteristic matrix of the ith coating film is equal to a characteristic matrix of an ideal single-layer coating film of which a refractive index is n_{f} and a film thickness d_{f} is λ/4/n_{f};
setting film thicknesses of (i−3) coating films among the i coating films in advance; and
determining film thicknesses of remaining three coating films among the i coating films, by solutions of three simultaneous equations derived from the characteristic matrix of the multilayer coating film.

8. The optical semiconductor device anti-reflection film design method according to claim 7, wherein
the anti-reflection film is formed by a four-layer coating film.

9. The optical semiconductor device anti-reflection film design method according to claim 7, wherein
the anti-reflection film is formed by a five-layer coating film.

10. The optical semiconductor device anti-reflection film design method according to claim 7, wherein
each of the coating films is made of one material of CeO₂, YF₃, ZnS, CeF₃, ZnSe, Al₂O₃, Ta₂O₅, SiO₂, and amorphous Si.

11. The optical semiconductor device according to claim 2, wherein
the optical semiconductor device is a semiconductor laser device.

12. The optical semiconductor device according to claim 2, wherein
the optical semiconductor device is a quantum-cascade semiconductor laser device.

13. The optical semiconductor device according to claim 2, wherein
each of the coating films is made of one material of CeO₂, YF₃, ZnS, CeF₃, ZnSe, Al₂O₃, Ta₂O₅, SiO₂, and amorphous Si.

14. The optical semiconductor device according to claim 3, wherein
the optical semiconductor device is a semiconductor laser device.

15. The optical semiconductor device according to claim 3, wherein
the optical semiconductor device is a quantum-cascade semiconductor laser device.

16. The optical semiconductor device according to claim 3, wherein
each of the coating films is made of one material of CeO₂, YF₃, ZnS, CeF₃, ZnSe, Al₂O₃, Ta₂O₅, SiO₂, and amorphous Si.

17. The optical semiconductor device anti-reflection film design method according to claim 8, wherein
each of the coating films is made of one material of CeO₂, YF₃, ZnS, CeF₃, ZnSe, Al₂O₃, Ta₂O₅, SiO₂, and amorphous Si.

18. The optical semiconductor device anti-reflection film design method according to claim 9, wherein
each of the coating films is made of one material of CeO₂, YF₃, ZnS, CeF₃, ZnSe, Al₂O₃, Ta₂O₅, SiO₂, and amorphous Si.
